(19) United States
(12) Patent Application Publication
(10) Pub. No.: US 2024/0401199 A1
(43) Pub. Date: Dec. 5, 2024

(54) SUBSTRATE PROCESSING APPARATUS AND SUBSTRATE PROCESSING METHOD

(71) Applicant: Tokyo Electron Limited, Tokyo (JP)

(72) Inventors: Hitoshi KATO, Iwate (JP); Yu WAMURA, Iwate (JP); Kazuhide HASEBE, Yamanashi (JP); Yuichiro MOROZUMI, Yamanashi (JP)

(21) Appl. No.: 18/668,699

(22) Filed: May 20, 2024

(30) Foreign Application Priority Data
May 30, 2023 (JP) 2023-088639

(51) Int. Cl. C23C 16/455; C23C 16/12; C23C 16/44; C23C 16/458

(52) U.S. Cl. CPC C23C 16/45551; C23C 16/12; C23C 16/4408; C23C 16/4412; C23C 16/45536; C23C 16/45565; C23C 16/4584

(57) ABSTRACT

A substrate processing apparatus includes a processing chamber, a turntable rotatably provided inside the processing chamber, a plurality of placing tables rotatable with respect to the turntable and placed with a plurality of substrates, respectively, at positions separated from a rotation center of the turntable, and a plurality of nozzles disposed at positions passing centers of the plurality of placing tables as the turntable rotates. The plurality of nozzles include a processing gas discharger configured to discharge a processing gas with respect to the plurality of substrates on the plurality of placing tables that move with the rotation of the turntable, in a radial range shorter than a radius of the plurality of substrates, and a gas suction section configured to suck a gas at an outer side of the processing gas discharger.

### CROSS-REFERENCE TO RELATED APPLICATIONS

This application is based upon and claims priority to Japanese Patent Application No. 2023-088639, filed on May 30, 2023, the entire contents of which are incorporated herein by reference.

### BACKGROUND

### 1. Field of the Invention

The present disclosure relates to substrate processing apparatuses and substrate processing methods.

### 2. Description of the Related Art

In recent years, due to increased integration and performance of semiconductor devices, it is desirable for a substrate processing apparatus to cope with promoting uniformity of a film thickness distribution or the like during a substrate processing, such as a film forming process. On the other hand, it is also desirable for the substrate processing apparatus to improve a productivity of the substrate processing.

As an example, Japanese Laid-Open Patent Publication No. 2021-111758 proposes a substrate processing apparatus that accommodates a plurality of substrates in a vacuum chamber, and performs the substrate processing on each substrate. In this substrate processing apparatus, the film forming process is performed on each substrate placed on each placing table, by rotating each placing table relative to a turntable while causing the turntable having a plurality of placing tables to revolve and supplying a processing gas into the vacuum chamber.

### SUMMARY

The disclosure provides a technique to promote uniformity of a substrate processing and to improve a productivity.

According to an aspect of the present disclosure, a substrate processing apparatus includes a processing chamber; a turntable rotatably provided inside the processing chamber; a plurality of placing tables rotatable with respect to the turntable and placed with a plurality of substrates, respectively, at positions separated from a rotation center of the turntable; and a plurality of nozzles disposed at positions passing centers of the plurality of placing tables as the turntable rotates, wherein the plurality of nozzles include a processing gas discharger configured to discharge a processing gas with respect to the plurality of substrates on the plurality of placing tables that move with the rotation of the turntable, in a radial range shorter than a radius of the plurality of substrates; and a gas suction section configured to suck a gas at an outer side of the processing gas discharger.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a plan view illustrating a substrate processing apparatus according to one embodiment;

FIG. 2 is a schematic cross sectional view of the substrate processing apparatus along a line II-II in FIG. 1;

FIG. 3 is a perspective view illustrating a configuration of a substrate holder;

FIG. 4A is a side cross sectional view illustrating a first nozzle;

FIG. 4B is a plan view of the first nozzle viewed from the substrate;

FIG. 5A is a side cross sectional view illustrating a second nozzle;

FIG. 5B is a plan view of the second nozzle viewed from the substrate;

FIG. 6 is a flow chart illustrating a processing flow of a substrate processing method;

FIG. 7A, FIG. 7B, FIG. 7C, and FIG. 7D are plan views illustrating an operation of a turntable during an adsorption process;

FIG. 8A is a plan view illustrating a trajectory of a substrate with respect to the first nozzle;

FIG. 8B, FIG. 8C, and FIG. 8D are explanatory diagrams illustrating examples of varying a speed of the turntable:

FIG. 9A, FIG. 9B, FIG. 9C, and FIG. 9D are plan views illustrating an operation of the turntable during an oxidation process;

FIG. 10 is a flow chart illustrating a processing flow of the substrate processing method according to a first modification; and

FIG. 11 is a plan view illustrating a substrate processing apparatus according to a second modification.

### DETAILED DESCRIPTION

Hereinafter, embodiments for implementing the present disclosure will be described with reference to the drawings. In the drawings, the same constituent elements are designated by the same reference numerals, and a redundant description thereof may be omitted.

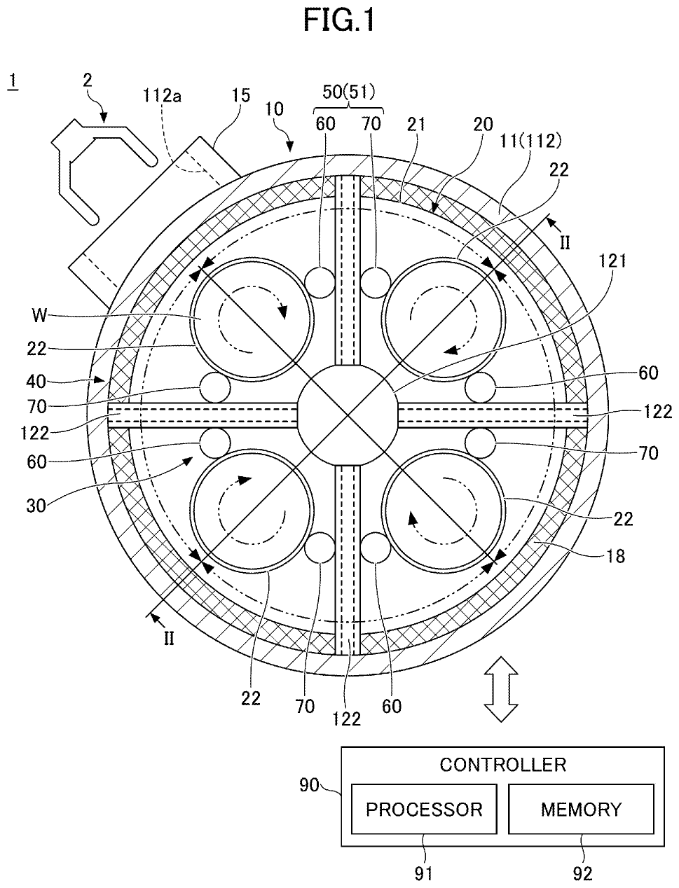

As illustrated in FIG. 1, a substrate processing apparatus 1 according to one embodiment is configured as an apparatus capable of simultaneously processing a plurality of (four in this example) substrates W. Specifically, the substrate processing apparatus 1 includes a processing chamber 10, a substrate holder 20, a gas supply 30, a gas exhauster 40, and a nozzle structure 50. The substrate processing apparatus 1 also includes a controller 90 that controls the operation of each component of the substrate processing apparatus 1. For the sake of convenience, illustration of a top plate 12 of the processing chamber 10 is omitted in FIG. 1.

The substrate processing apparatus 1 according to one embodiment performs a film forming process by atomic layer deposition ALD) or a molecular layer deposition (MLD), as a substrate processing. The substrate processing apparatus 1 is not limited to the configuration for performing the film forming process as the substrate processing, and may be an apparatus that performs an etching process to etch a film on the substrate W, a cleaning process to remove deposits on the substrate W, or the like, for example.

The substrate W to be subjected to substrate processing may be a semiconductor wafer formed of a semiconductor such as a silicon semiconductor, a compound semiconductor, an oxide semiconductor, or the like. The substrate W may have a recessed pattern, such as a trench, a via, or the like.

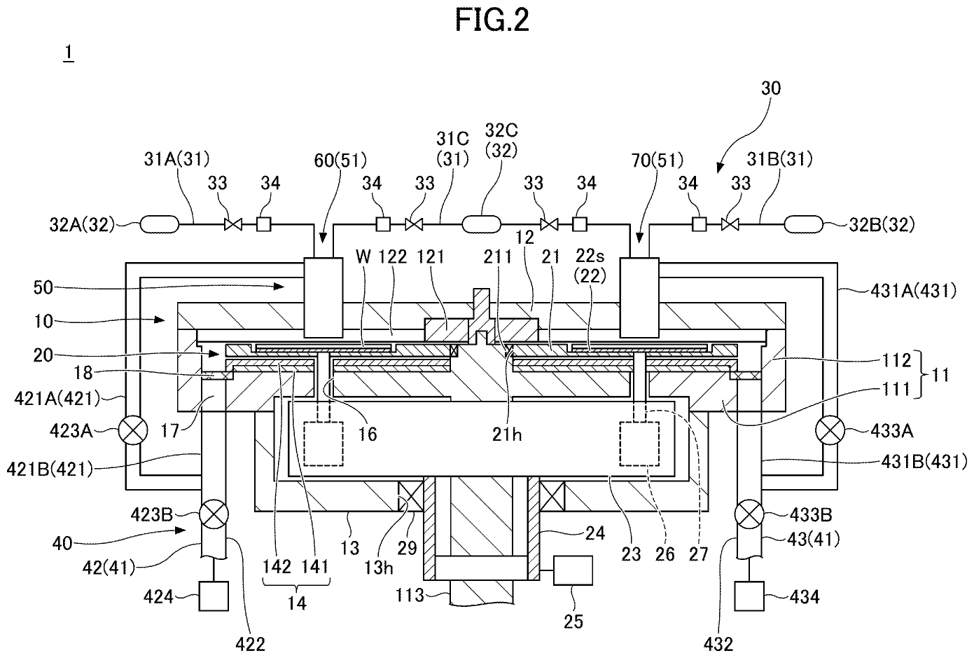

As illustrated in FIG. 1 and FIG. 2, the processing chamber 10 is formed of quartz or the like, and has a decompressible internal space that can accommodate a plurality of substrates W. The processing chamber 10 has a perfect circular shape in a plan view, and is formed to a cylindrical shape having a length in a vertical direction shorter than a diameter in a horizontal direction. The processing chamber 10 may be formed in a rectangular tube shape (having a rectangular shape in the plan view). Specifically, the processing chamber 10 includes a main body 11, the top plate 12 covering a ceiling of the main body 11, and an accommodating chamber 13 connected below the main body 11, as illustrated in FIG. 2.

The main body 11 includes a disk-shaped bottom wall 111, and a sidewall 112 that protrudes upward in the vertical direction from an outer edge of the bottom wall 111. The bottom wall 111 and the sidewall 112 are integrally connected to each other, and surround a concave space on an inner side the bottom wall 111 and the sidewall 112. In addition, the main body 11 has a fixed shaft 113 that fixes and supports the bottom wall 111, at a center of the bottom wall 111.

A temperature adjuster 14, that adjusts a temperature of each substrate W held by the substrate holder 20, is provided on an upper surface of the bottom wall 111. The temperature adjuster 14 includes a heater 141 provided on the bottom wall 111, and a cover 142 disposed above the heater 141, for example. The heater 141 is formed to a disk shape having a heating wire therein, for example, and is connected to the controller 90 via a temperature adjustment drive (not illustrated) or the like. Thus, a temperature of the heater 141 is adjusted by the controller 90. The cover 142 covers substantially the entire heater 141, so as to prevent the gas supplied from the gas supply 30 to the internal space from making contact with the heater 141. The temperature adjuster 14 is not limited to the heater 141, and may have a configuration suited for adjusting the temperature of each substrate W, such as a configuration in which a temperature adjusting medium having a temperature thereof adjusted by a heat exchanger, a chiller, or the like is circulated through a flow path (not illustrated) formed inside the bottom wall 111 or the top plate 12, or the like.

The fixed shaft 113 supports the main body 11, and includes therein a space (not illustrated) for supplying power to the temperature adjuster 14 or for circulating the temperature adjusting medium. Further, the fixed shaft 113 protrudes upward in the vertical direction from the bottom wall 111 to support the top plate 12, and axially supports an inner side of the turntable 21 of the substrate holder 20.

The top plate 12 is fixed to the sidewall 112 so as to close the concave space of the main body 11, thereby forming the internal space of the processing chamber 10 in cooperation with the main body 11. A seal member (not illustrated) capable of airtightly closing the internal space is provided at a contact portion between the sidewall 112 and the top plate 12.

The processing chamber 10 also includes a central fixing portion 121, that connects the fixed shaft 113 and the top plate 12 to each other, at a center of the top plate 12. Further, the processing chamber 10 includes a plurality of (four in this example) partition wall members 122 extending radially from the central fixing portion 121 toward the sidewall 112 of the main body 11, as also illustrated in FIG. 1.

Each partition wall member 122 is connected to a lower surface of the top plate 12 and holds a first nozzle 60 and a second nozzle 70 of the nozzle structure 50 which will be described later. Each partition wall member 122 protrudes downward from the top plate 12, and a lower end of each partition wall member 122 is disposed at a position closer to an upper surface of the turntable 21 of the substrate holder 20 than the first nozzle 60 and the second nozzle 70 are to the upper surface of the turntable 21. Each partition wall member 122 partitions a space above the turntable 21 of the processing chamber 10. The four partition wall members 122 partition the internal space of the processing chamber 10 into four sections divided for every 90° interval above the turntable 21 (hereinafter, the four divided sections may also be referred to as first, second, third, and fourth quadrants Q1, Q2, Q3, and Q4). However, the internal space is not completely partitioned, and adjacent divided sections can communicate with each other below the partition wall member 122. The partition wall member 122 may have a flow path (not illustrated) therein, and may be configured to discharge a purge gas from one or more discharge ports (not illustrated) provided in a lower surface of the partition wall member 122 (the surface opposing the turntable 21) and communicating with the flow path. By discharging the purge gas, the gases supplied to the first quadrant Q1 through the fourth quadrant Q4 can be separated from one another.

The processing chamber 10 includes a side opening 112a at a suitable position (a circumferential intermediate position of one of four divided regions) of the sidewall 112 of the main body 11. A transport device 2, configured to transport the substrate W, enters and exits the processing chamber 10 through the side opening 112a. A substrate processing system, including the substrate processing apparatus 1 and the transport device 2, loads and unloads each substrate W through the side opening 112a. A gate valve 15, configured to open and close the side opening 112a, is provided in the sidewall 112.

As illustrated in FIG. 1 and FIG. 2, the substrate holder 20 of the substrate processing apparatus 1 holds four substrates W accommodated inside the processing chamber 10 so as to be revolvable and rotatable. For this reason, the substrate holder 20 includes a turntable 21, and a plurality of (four in this example) placing tables 22 that support the substrates W on an upper surface at an outer peripheral portion of the turntable 21. In addition, the substrate holder 20 includes a support 23 configured to support the turntable 21, a rotating shaft 24 configured to rotatably support the support 23, and a revolution drive 25 configured to rotate the rotating shaft 24, as a configuration for causing each placing table 22 to revolve. The substrate holder 20 further includes a rotation drive 26 provided inside the support 23, and a rotating shaft 27 protruding from the rotation drive 26, as a configuration for causing each placing table 22 to rotate.

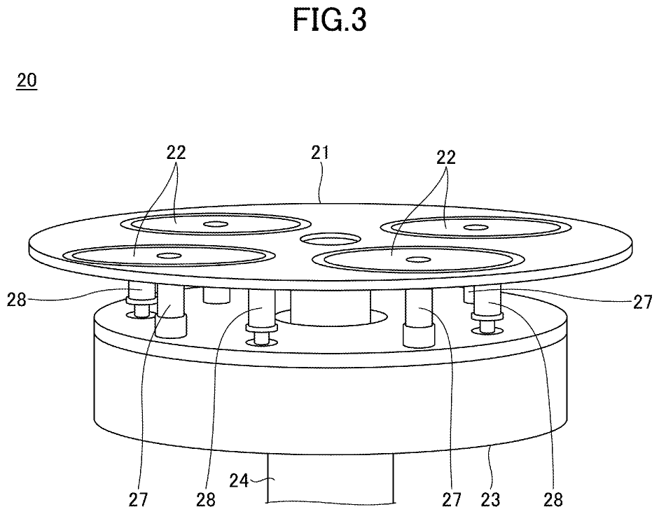

The turntable 21 is rotatable around the fixed shaft 113 inside the internal space of the processing chamber 10. The turntable 21 is formed of quartz or the like, and has an annular plate shape. A bearing hole 21h is formed in a center of the turntable 21, and the fixed shaft 113 is axially supported in the bearing hole 21h via a bearing 211 made of a magnetic fluid or the like. As illustrated in FIG. 3, a lower surface of the turntable 21 is fixed to a plurality of support columns 28 protruding upward from the support 23. Each of the support columns 28 extends between an inside and an outside of the main body 11, via a passage 16 that is provided to penetrate the bottom wall 111 of the processing chamber 10 and the temperature adjuster 14 in a thickness direction. Accordingly, when the support 23 rotates, each of the support columns 28 rotates inside the passage 16, and each of the support columns 28 can transmit a rotational force thereof to the turntable 21.

The four placing tables 22 are provided at the same distance (same radial position) from the center of the turntable 21, and are arranged at equal intervals (that is, at angular intervals of 90°) along a circumferential direction. Each of the placing tables 22 is formed of quartz, and has a perfect circular shape slightly larger than the substrate W. Each of the placing tables 22 has a flat placing surface 22s on which the substrate W is placed, on an upper surface thereof. The rotating shaft 27 is connected to a lower surface of each of the placing tables 22.

The rotation drive 26 is provided below each of the placing tables 22 in the vertical direction, and rotatably supports the rotating shaft 27. The rotation drive 26 includes a motor, such as a servo motor or the like, and a rotation transmission mechanism (both not illustrated), and the rotation drive 26 is connected to the controller 90. The rotation drive 26 rotates under the control of the controller 90, to rotate the placing table 22 opposing the rotation drive 26 in the vertical direction, via the rotating shaft 27 at a suitable speed.

Each rotating shaft 27 passes through an upper portion of the support 23, the bottom wall 111 of the main body 11, and the passage 16 of the temperature adjuster 14, and penetrates a hole of the turntable 21. The rotating shaft 27 is connected to the center of the placing table 22, and rotates the placing table 22 around the center. Each rotating shaft 27 and each support column 28 are arranged above the support 23 in the same circumferential direction, and can rotate together inside the passage 16.

The support 23 is provided below the main body 11 in the vertical direction, and is connected to the rotating shaft 24 at a center portion thereof. The support 23 rotates around the fixed shaft 113 according to the rotation of the rotating shaft 24. In addition, the support 23 is accommodated inside the accommodating chamber 13 that is connected to the main body 11 of the processing chamber 10, and the support is rotatable relative to the accommodating chamber 13.

The rotating shaft 24 extends in the vertical direction, and penetrates a through hole 13h of the accommodating chamber 13. A seal member 29, such as a magnetic fluid seal or the like, is provided between the rotating shaft 24 and the through hole 13h of the accommodating chamber 13.

A revolution drive 25 is connected to a lower portion of the rotating shaft 24. The revolution drive 25 includes a motor, such as a servo motor or the like, and a rotation transmission mechanism (both not illustrated), and the revolution drive 25 is connected to the controller 90. The revolution drive 25 rotates under the control of the controller 90 to rotate the rotating shaft 24, thereby integrally rotating the turntable 21 and the support 23.

The revolution drive 25 according to the embodiment causes the turntable 21 to reciprocate in the circumferential direction. For example, the revolution drive 25 performs an operation of rotating the turntable 21 clockwise by 90° in FIG. 1, and thereafter rotating the turntable 21 counterclockwise by 90° in FIG. 1. This operation of the turntable 21 will be described later in more detail.

As illustrated in FIG. 1 and FIG. 2, the gas supply 30 includes a plurality of supply paths 31 through which gases, such as a processing gas (adsorption gas, reaction gas), a purge gas, or the like are circulated outside the processing chamber 10, and supplies the gases into the processing chamber 10 through each of the plurality of supply paths 31.

A suitable gas is selected as the processing gas supplied to the processing chamber 10, according to a type of film to be formed on the substrate W. When forming a silicon oxide (SiO₂) film, for example, a silicon-containing gas, such as a silane-based gas or the like, may be used as the adsorption gas. In addition, an oxygen-containing gas, such as oxygen (O₂) gas, ozone (O₃) gas, or the like may be used as the reaction gas. Further, an inert gas, such as nitrogen gas (N₂), argon (Ar) gas, or the like may be used as the purge gas.

As illustrated in FIG. 2, the plurality of supply paths 31 include an adsorption gas supply path 31A for circulating the adsorption gas, a reaction gas supply path 31B for circulating the reaction gas, and a purge gas supply path 31C for circulating the purge gas. The adsorption gas supply path 31A is connected to the first nozzle 60 of the nozzle structure 50. The reaction gas supply path 31B is connected to the second nozzle 70 of the nozzle structure 50. The purge gas supply path 31C is connected to both the first nozzle 60 and the second nozzle 70. The purge gas supply path 31C may be connected to the flow path of the partition wall member 122 to supply the purge gas.

As described above, four first nozzles 60 and four second nozzles 70 are provided, and the adsorption gas supply path 31A, the reaction gas supply path 31B, and the purge gas supply path 31C branch at suitable positions to connect to the first nozzles 60 and/or the second nozzles 70.

Each of the plurality of supply paths 31 includes one or a plurality of tanks 32 for storing gas, one or a plurality of open/close valves 33 for opening and closing the supply path 31, and one or a plurality of flow rate regulators 34 for regulating the flow rate of the gas flowing through the flow path of the supply path 31. The tank 32 includes an adsorption gas tank 32A for storing the adsorption gas, a reaction gas tank 32B for storing the reaction gas, and a purge gas tank 32C for storing the purge gas. The open/close valve 33 and the flow rate regulator 34 are connected to the controller 90. The controller 90 opens the open/close valve 33 of each supply path 31 at a suitable timing of the substrate processing, and adjusts the flow rate of the gas by the flow rate regulator 34, so as to supply a target gas to the processing chamber 10.

On the other hand, the gas exhauster 40 includes a plurality of exhaust paths 41 through which the gases (reacted gas, unreacted gas, purge gas, or the like) are circulated outside the processing chamber 10, and discharges the gases supplied into the processing chamber through the respective exhaust paths 41. In the present embodiment, the plurality of exhaust paths 41 are divided into two systems according to the first nozzle 60 and the second nozzle 70 of the nozzle structure 50 which will be described later.

A first exhaust path 42 is connected to the first nozzle 60 and a position in a vicinity thereof, and mainly exhausts the gas discharged from the first nozzle 60. The first exhaust path 42 includes a plurality of (two in this example) branched exhaust paths 421, and a merged exhaust path 422 where the branched exhaust paths 421 are merged to exhaust the merged gases. One branched exhaust path 421A is directly connected to the first nozzle 60, and exhausts the gas from the first nozzle 60. The branched exhaust path 421A is provided with a pressure regulator valve 423A for regulating a pressure of the gas sucked by the first nozzle 60.

The other branched exhaust path 421B is connected to the bottom wall 111 of the processing chamber 10, and exhausts the gas in the internal space in a periphery of the turntable 21. The bottom wall 111 is provided with an exhaust groove 17 that extends annularly (refer also to FIG. 1). The branched exhaust path 421B communicates with a bottom of the exhaust groove 17. In addition, an exhaust net 18 is preferably provided at an upper opening of the exhaust groove 17, in order to make a conductance uniform in the circumferential direction when exhausting the gas.

A suction mechanism 424 (for example, a turbo molecular pump or a vacuum pump) is connected to the merged exhaust path 422, in order to suck the gas in the entire first exhaust path 42. Further, the merged exhaust path 422 is provided with a pressure regulator valve 423B for regulating a pressure of the gas sucked in the entire first system.

The second exhaust path 43 is connected to the second nozzle 70 and a position in a vicinity thereof, and mainly exhausts the gas discharged from the second nozzle 70. The second exhaust path 43 also includes a plurality of (two in this example) branched exhaust paths 431, and a merged exhaust path 432 where the branched exhaust paths 431 are merged to exhaust the merged gas, similarly to the first exhaust path 42. One branched exhaust path 431A is connected to the second nozzle 70, and exhausts the gas from the second nozzle 70. The branched exhaust path 431A is provided with a pressure regulator valve 433A for regulating a pressure of the gas sucked in the second nozzle 70. The other branched exhaust path 431B is connected to the bottom wall 111 (the bottom of the exhaust groove 17) of the processing chamber 10, and exhausts the gas in the internal space in the periphery of the turntable 21.

The merged exhaust path 432 is provided with a suction mechanism 434 (for example, a turbo molecular pump or a vacuum pump) for sucking the gas in the entire second exhaust path 43. Further, the merged exhaust path 432 is provided with a pressure regulator valve 433B for regulating the gas pressure to be sucked in the entire second system.

The nozzle structure 50 discharges the processing gas and the purge gas to the upper surface (front surface) of each of the substrates W at suitable positions inside the processing chamber 10, and sucks the gas above each of the substrates W. The nozzle structure 50 includes a plurality of nozzles 51 provided in the top plate 12 of the processing chamber 10 and configured to supply the gases. The plurality of nozzles 51 include the first nozzle 60 that discharges the processing gas and the purge gas, and a second nozzle 70 that discharges the reaction gas and the purge gas. Four first nozzles 60 and four second nozzles 70 are provided in the processing chamber 10. In other words, the nozzle structure 50 includes a total of eight nozzles 51.

The first nozzles 60 and the second nozzles 70 are fixed to the four partition wall members 122, respectively. For example, each partition wall member 122 holds the first nozzle 60 on a side surface on the counterclockwise side in FIG. 1, and holds the second nozzle 70 on a side surface on the clockwise side in FIG. 1. In other words, one first nozzle 60 and one second nozzle 70 are disposed in each of first through fourth quadrants Q1 through Q4 partitioned by the partition wall members 122. By providing the four partition wall members 122 at equal intervals (at 90° intervals) in the circumferential direction, the four first nozzles 60 are also arranged at equal intervals (at 90° intervals), and the four second nozzles 70 are also arranged at equal intervals (at 90° intervals).

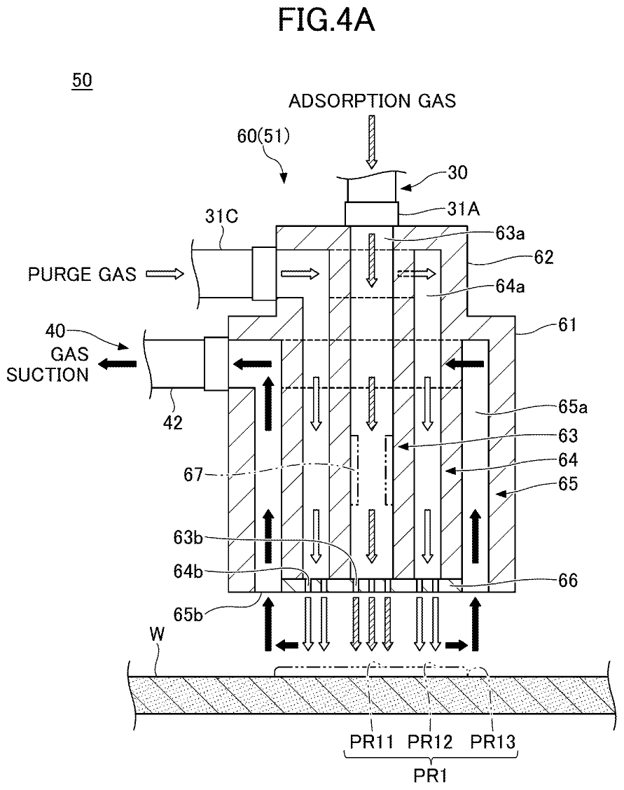

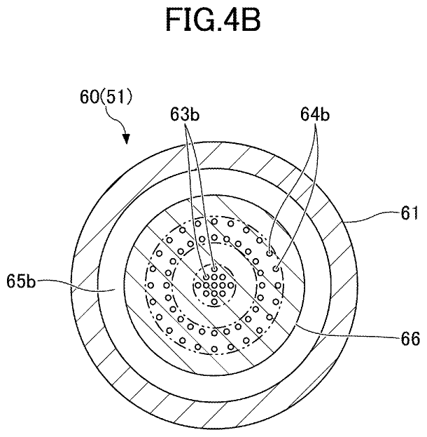

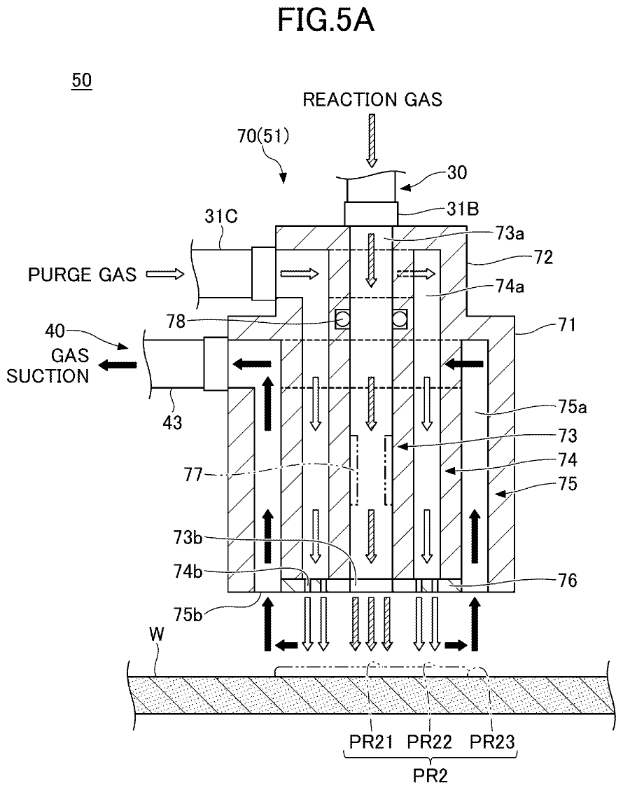

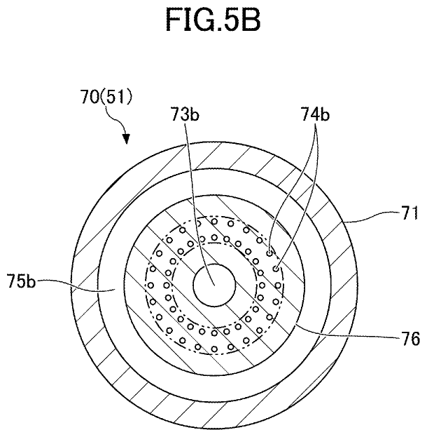

As illustrated in FIG. 2, the first nozzle 60 and the second nozzle 70 are provided to penetrate the top plate 12 of the processing chamber 10, and are connected to the gas exhauster 40 and the gas supply 30 outside the processing chamber 10, respectively. The first nozzle 60 and the second nozzle 70 inside the processing chamber 10 discharge and suck the gas with respect to the lower side in the vertical direction. Thus, a first processing region PR1 (refer to FIG. 4A) is formed on the lower side of the first nozzle 60 in the vertical direction. In addition, a second processing region (refer to FIG. 5A) is formed on the lower side in the vertical direction of the second nozzle 70.

As illustrated in FIG. 4A and FIG. 4B, the first nozzle 60 includes a cylindrical head 61, and a protruding part 62 connected to an upper portion of the head 61. The first exhaust path 42 (the branched exhaust path 421A) of the gas exhauster 40 is connected to the head 61. The adsorption gas supply path 31A and the purge gas supply path 31C of the gas supply 30 are connected to the protruding part 62. Thus, the first nozzle 60 forms the first processing region PR1 where the adsorption gas and the purge gas are discharged to the substrate W and the discharged adsorption gas and purge gas are sucked during the substrate processing.

Specifically, the first nozzle 60 includes a processing gas discharger 63 that discharges the adsorption gas, at the center of the head 61 and the center of the protruding part 62. The processing gas discharger 63 discharges the adsorption gas (processing gas) to a radial range shorter than the radius of the substrate W. For example, the radial range of the processing gas discharger 63 may be set to approximately ½ to approximately 1/10 of the radius of the substrate W.

The processing gas discharger 63 is a part that is surrounded by an inner wall spanning the head 61 and the protruding part 62, and a bottom wall of the head 61 opposing the substrate W. The bottom wall is formed of a discharge plate 66 that is fixed to the head 61, for example. The processing gas discharger 63 has a discharge passage 63a therein, and a plurality of discharge holes 63b formed in the bottom wall and communicating with the discharge passage 63a. The adsorption gas supply path 31A is connected to the protruding part 62, so as to communicate with the discharge passage 63a. The processing gas discharger 63 may include a heater 67 for heating the adsorption gas, provided inside the discharge passage 63a.

The plurality of discharge holes 63b of the processing gas discharger 63 are disposed in a matrix arrangement at a center of the bottom surface of the head 61. Hence, the processing gas discharger 63 forms a substantially circular adsorption gas discharge region PR1l at a center of the first processing region PR1. The adsorption gas discharge region PR1l has a size that is sufficiently narrow with respect to an area of the entire substrate W.

Further, the first nozzle 60 includes a purge gas discharger 64 for discharging the purge gas, provided at a position in a periphery of the processing gas discharger 63. The purge gas discharger 64 is a part that is surrounded between an inner wall and an outer wall of the protruding part 62, between the inner wall and the partition wall of the head 61, and the bottom wall. The purge gas discharger 64 has a discharge passage 64a therein, and a plurality of discharge holes 64b formed in the bottom wall and communicating with the discharge passage 64a. The purge gas supply path 31C is connected to the protruding part 62, so as to communicate with the discharge passage 64a.

Each discharge hole 64b of the purge gas discharger 64 has an annular shape surrounding each discharge hole 63b of the processing gas discharger 63. Accordingly, the purge gas discharger 64 forms an annular purge gas discharge region PR12 on an outer side of the adsorption gas discharge region PR11. The purge gas discharger 64 can prevent the adsorption gas discharged by the processing gas discharger 63 from spreading to the outer side, by discharging the purge gas during the substrate processing.

The first nozzle 60 includes a gas suction section 65 that sucks the gas, provided at a position in a periphery of the purge gas discharger 64. The gas suction section 65 is a part that is surrounded by the partition wall and the outer wall of the head 61. The gas suction section 65 has a suction path 65a therein, and a continuous opening 65b communicating with the suction path 65a. The first exhaust path 42 is connected to the suction path 65a so as to communicate with the suction path 65a. For example, the flow path inside the first exhaust path 42 has a cross sectional area larger than cross sectional areas of the flow path of the adsorption gas supply path 31A and the flow path of the purge gas supply path 31C.

The opening 65b is formed in an annular shape surrounding an outer periphery of the bottom wall of the head 61. That is, the gas suction section 65 forms an annular suction region PR13 on the outer side of the purge gas discharge region PR12. Thus, the gas suction section 65 can smoothly suck the adsorption gas and the purge gas discharged onto the substrate W, in a periphery of the purge gas during the substrate processing.

As illustrated in FIG. 5A and FIG. 5B, the second nozzle 70 is basically formed in a manner similar to the first nozzle 60, and has a cylindrical head 71, and a protruding part 72 provided continuously with an upper portion of the head 71. The second exhaust path 43 (the branched exhaust path 431A) of the gas exhauster 40 is connected to the head 71. The reaction gas supply path 31B and the purge gas supply path 31C of the gas supply 30 are connected to the protruding part 62. Hence, the second nozzle 70 forms a second processing region PR2 for discharging the reaction gas and the purge gas to the substrate W and sucking the discharged reaction gas and purge gas during the substrate processing.

Specifically, the second nozzle 70 includes a processing gas discharger 73 for discharging the reaction gas, at the center of the head 71 and the center of the protruding part 72. The processing gas discharger 73 discharges a reaction gas (processing gas) to a radial range shorter than the radius of the substrate W. For example, the radial range of the processing gas discharger 73 may be set to approximately ½ to approximately 1/10 of the radius of the substrate W.

The processing gas discharger 73 is a part surrounded by an inner wall spanning the head 71 and the protruding part 72, and a bottom wall (a discharge plate 76) of the head 71 opposing the substrate W. The processing gas discharger 73 has a discharge passage 73a therein, and a discharge port 73b formed in the bottom wall and communicating with the discharge passage 73a. The reaction gas supply path 31B is connected to the protruding part 72, so as to communicate with the discharge passage 73a. The discharge port 73b has a perfect circular shape that communicates in series with the discharge passage 73a, but the second nozzle 70 is not limited to this discharge port 73b, and may be configured to include a plurality of discharge holes, similar to the first nozzle 60. The processing gas discharger 73 may include a heater 77 for heating the reaction gas, provided inside the discharge passage 73a.

Further, the processing gas discharger 73 may be configured to discharge the reaction gas as it is (or after heating) or discharge the reaction gas after plasmatizing (radicalizing) the reaction gas according to the substrate processing. Hereinafter, the configuration of the processing gas discharger 73 that plasmatizes and discharges the reaction gas will be described in detail. The processing gas discharger 73 includes an antenna 78 for the plasma, extending around an outer peripheral surface of the inner wall of the protruding part 72. The antenna 78 is connected to a high-frequency power supply (not illustrated) provided outside the processing chamber via an interconnect (not illustrated). During the substrate processing, high-frequency power is supplied from the high-frequency power supply to the antenna 78 via the interconnect, thereby generating the plasma in the reaction gas flowing through the discharge passage 73a.

When plasmatizing the reaction gas, a gas mixture including a suitable mixture of O₂, H₂, NH₃, Ar, N₂, or the like, for example, may be used. Moreover, in order to form an oxide film having a high quality, the purge gas used when generating the plasma preferably includes O₃. In this case, when discharging the reaction gas, the processing gas discharger 73 forms a substantially circular plasmatized reaction gas discharge region PR21 at a center of the second processing region PR2. The reaction gas discharge region PR21 has a sufficiently narrow size with respect to an area of the entire substrate W.

Further, the second nozzle 70 includes a purge gas discharger 74 for discharging the purge gas, provided at a position in a periphery of the processing gas discharger 73. The purge gas discharger 74 is a part surrounded between the inner wall and the outer wall of the protruding part 72, between the inner wall and the partition wall of the head 71, and the bottom wall. The purge gas discharger 74 has a discharge passage 74a therein, and a plurality of discharge holes 74b formed in the bottom wall and communicating with the discharge passage 74a. The purge gas supply path 31C is connected to the protruding part 72, so as to communicate with the discharge passage 74a.

Each discharge hole 74b of the purge gas discharger 74 has an annular shape surrounding each discharge port 73b of the processing gas discharger 73. Thus, the purge gas discharger 74 forms an annular purge gas discharge region PR22 on an outer side of the reaction gas discharge region PR21. The purge gas discharger 74 can prevent the reaction gas discharged by the processing gas discharger 73 from spreading to the outer side by discharging the purge gas during the substrate processing.

In addition, the second nozzle 70 includes a gas suction section 75 that sucks the gas, provided at a position in a periphery of the purge gas discharger 74. The gas suction section 75 is a part surrounded by the partition wall and the outer wall of the head 71. The gas suction section 75 has a suction path 75a therein, and a continuous opening 75b communicating with the suction path 75a. The second exhaust path 43 is connected to the suction path 75a so as to communicate with the suction path 75a. For example, the flow path inside the second exhaust path 43 has a cross sectional area larger than cross sectional areas of the flow path of the reaction gas supply path 31B and the flow path of the purge gas supply path 31C.

The opening 75b is formed in an annular shape surrounding an outer periphery of the bottom wall of the head 71. That is, the gas suction section 75 forms an annular suction region PR23 on an outer side of the purge gas discharge region PR22. Thus, the gas suction section 75 can smoothly suck the reaction gas and the purge gas discharged onto the substrate W, in a periphery of the purge gas during the substrate processing.

The center of the first nozzle 60 and the center of the second nozzle 70 are disposed so as to oppose the center of each of the placing tables 22 provided on the turntable 21. For this reason, the first nozzle 60 and the second nozzle 70 pass the center of the substrate W placed on each of the placing tables 22, above the substrate in the vertical direction, as the turntable 21 rotates. Because each of the placing tables 22 rotates during the substrate processing, the first nozzle 60 and the second nozzle 70 as a result can oppose the entire surface of the substrate W.

Returning now to the description of FIG. 1, a computer including a processor 91, a memory 92, an input/output interface (not illustrated), or the like may be applied to the controller 90 that controls the substrate processing apparatus 1. The processor 91 is one or a combination of a central processing unit (CPU), a graphics processing unit (GPU), an application specific integrated circuit (ASIC), a field programmable gate array (FPGA), a circuit including a plurality of discrete semiconductors devices, or the like. The memory 92 is a suitable combination of a volatile memory and a nonvolatile memory (for example, a compact disc, a digital versatile disc (DVD), a hard disk, a flash memory, or the like).

The memory 92 stores a program for operating the substrate processing apparatus 1, and recipes such as process conditions or the like of substrate processing. The processor 91 controls each component of the substrate processing apparatus 1 by reading the program from the memory 92 and executing the read program. The controller 90 may be configured by a host computer or a plurality of client computers that communicate information via a network.

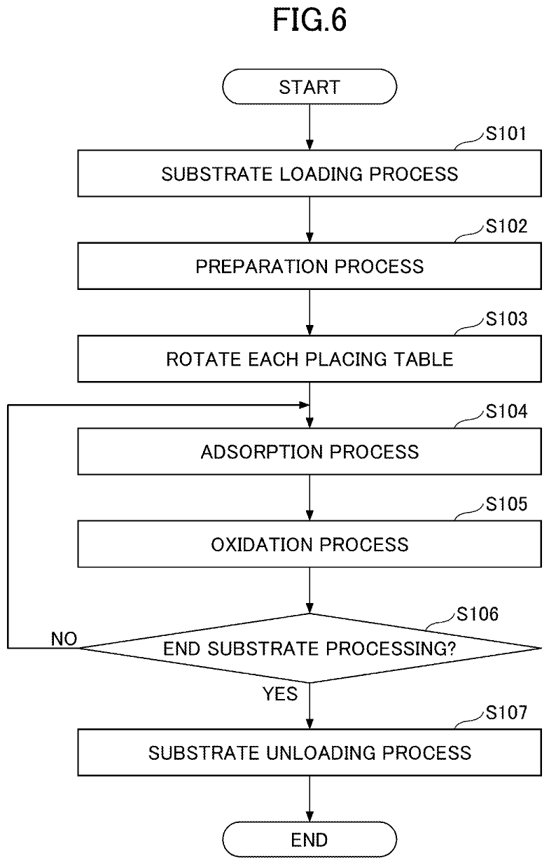

The substrate processing apparatus 1 according to the present embodiment is basically configured as described above, and a substrate processing method thereof will now be described below with reference to FIG. 6 through FIG. 9D.

The controller 90 controls each component of the substrate processing apparatus 1 to successively perform processes of steps S101 through S107 illustrated in the flow chart of FIG. 6, thereby performing a film forming process on each substrate W inside the processing chamber 10. In the following substrate processing method, an operation of reciprocating the turntable 21 clockwise and counterclockwise in a state where each of the placing tables 22 is rotated, will be described in detail.

Specifically, the controller 90 first performs a substrate loading process (step S101 in FIG. 6). As illustrated in FIG. 1, during the substrate loading process, the controller 90 opens the gate valve 15 and transports the substrate W by the transport device 2, to load the substrate W into the processing chamber 10 through the side opening 112a. In the processing chamber 10, the turntable 21 is rotated by a predetermined angle every time one substrate W is loaded, so as to place the substrates W on the placing tables 22, respectively. For example, when the substrates W are placed on all of the four placing tables 22, respectively, the controller 90 ends the substrate loading process and closes the gate valve 15.

Next, the controller 90 performs a preparation process for the film forming process (step S102 in FIG. 6) For example, during the preparation process, the controller 90 operates the gas supply 30 and the gas exhauster 40 to exhaust the gas inside the processing chamber 10 while supplying the purge gas from the first nozzle 60 and the second nozzle 70, thereby setting the internal space of the processing chamber 10 to a target pressure. The target pressure can be suitably set according to the type of substrate processing or the like, and can be set in a range of 1 Torr to 10 Torr, for example.

Further, during the preparation process, the controller 90 operates the temperature adjuster 14 to adjust (heat) the temperature of each substrate W held by the substrate holder 20 to a target temperature. The target temperature can also be suitably set according to the type of substrate processing or the like, and can be set in a range of approximately 100° C. to approximately 800° C., for example.

When the preparation process is performed, the controller 90 operates each rotation drive 26 to start rotating each placing table 22 (step S103 in FIG. 6). Thus, the substrate W placed on each placing table 22 rotates about the center thereof. A rotational speed of each placing table 22 is preferably set according to a speed (revolving speed) of the turntable 21 which will be described later, and is set in a range of 10 rpm to 1000 rpm, for example. In particular, the rotational speed of the placing table 22 may be set higher than the revolving speed of the turntable 21. Further, the controller 90 continues the rotation of each placing table 22 at the set rotational speed until the film forming process ends.

Next, the controller 90 performs an adsorption process as a film forming process (step S104 in FIG. 6). Specifically, the controller 90 operates the gas exhauster 40 to suck the gas by each of the first nozzles 60, while operating the gas supply 30 to discharge the adsorption gas and the purge gas from each of the first nozzles 60. In this state, the controller 90 stops the discharge and suction of the gas by each of the second nozzles 70. Further, the controller 90 rotates the turntable 21 in a first direction (for example, clockwise) while maintaining the rotation of each of the placing tables 22.

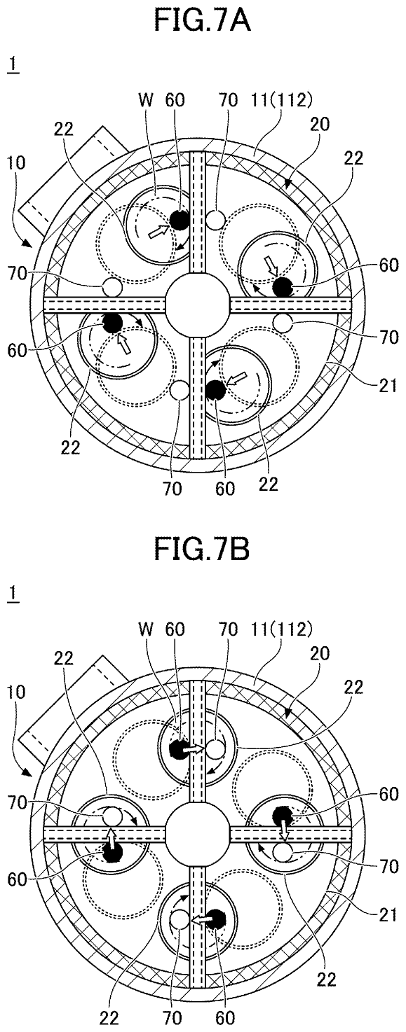

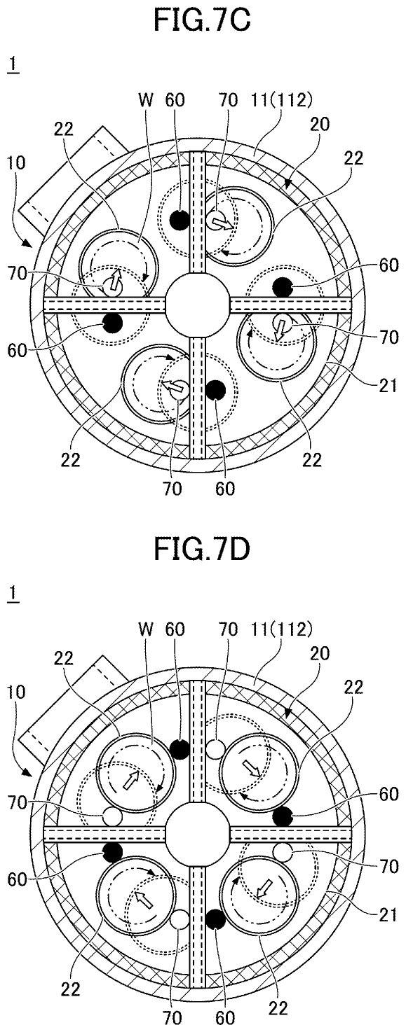

As illustrated in FIG. 7A, each substrate W placed on each placing table 22 enters below the first nozzle 60 in the vertical direction from a leading end in the clockwise direction, due to the clockwise rotation (revolution) of the turntable 21. In this state, each placing table 22 rotates at a rotational speed higher than the revolving speed of the turntable 21. An outer edge of each substrate W placed on each placing table 22 continues to rotate in the circumferential direction below the first nozzle 60 in the vertical direction, and thus, the outer edge of each substrate W opposes the first nozzle 60 for the entire circumference in the circumferential direction.

The first nozzle 60 forms the first processing region PR1 for discharging the adsorption gas and the purge gas and sucking the gases, below the first nozzle 60 in the vertical direction (refer to FIG. 4A). Thus, the adsorption gas is adsorbed onto the outer edge of the upper surface of each substrate W passing below the first nozzle 60 in the vertical direction. In FIG. 7A through FIG. 7D, the nozzles 51 that discharge and suck the gas are indicated by black circular marks. Further, as illustrated in FIG. 7B, each substrate W passes below the partition wall member 122 in the vertical direction due to the clockwise rotation of the turntable 21, and the adsorption gas discharged from the first nozzle 60 located at a position in the vicinity of the partition wall member 122 is also adsorbed onto a central portion of the upper surface of each substrate W.

As illustrated in FIG. 7C, a trailing end in the clockwise direction of each substrate W passes below the first nozzle 60 in the vertical direction, due to the clockwise rotation of the turntable 21. For example, the substrate W located in the first quadrant Q1 moves to the second quadrant Q2 by passing through the first nozzle 60 and the partition wall member 122. Further, each substrate W opposes the first nozzle 60 a plurality of times as the placing table 22 rotates, while passing below the first nozzle 60 and the partition wall member 122 in the vertical direction. As a result, the adsorption gas is adsorbed onto the entire surface of each substrate W.

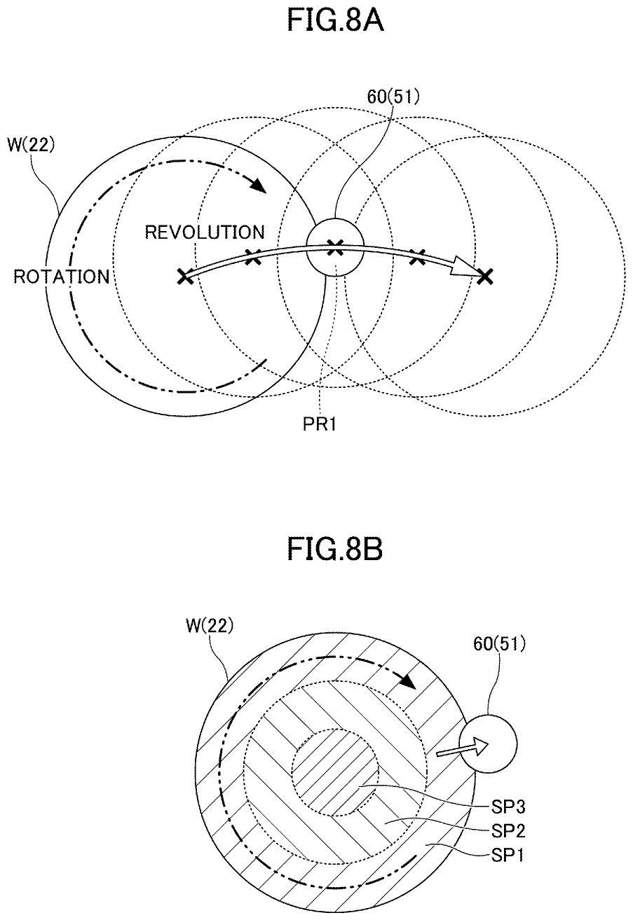

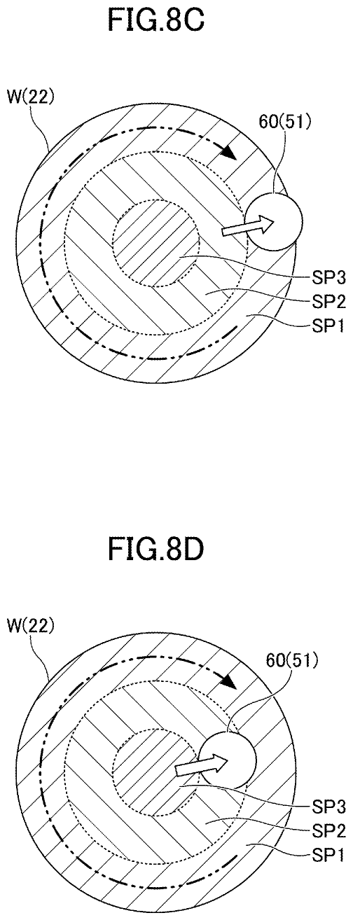

As illustrated in more detail in FIG. 8A, the substrate W passes below the first nozzle 60 in the vertical direction along an arcuate trajectory of the turntable 21, due to the clockwise rotation of the turntable 21. In addition, the first nozzle 60 passes the radius of the substrate W twice, while the substrate W moves from the leading end to the trailing end in the clockwise direction relative to the first nozzle 60. The substrate processing apparatus 1 can cause the first processing region PR1 to oppose the entire circumference of the substrate W in the circumferential direction by the rotation of the substrate W about the center thereof, while varying the radial position of the first processing region PR1 on the substrate W. For example, the controller 90 sets the rotational speed of the substrate W (placing table 22) to a speed such that the first processing region PR1 passes the radial position of the substrate W on the order of once to ten times. In this case, it possible to satisfactorily adsorb the adsorption gas onto the entire surface of the substrate W.

Further, the first nozzle 60 forms the purge gas discharge region PR12 on the outer side of the adsorption gas discharge region PR11, and thus, it is possible to easily control the adsorption gas discharge region PR1l by preventing the adsorption gas from spreading. Further, the first nozzle 60 sucks the gas in the suction region PR13 on the outer side of the purge gas discharge region PR12, thereby reducing the adsorption gas remaining near the upper surface of the substrate W, and preventing the adsorption gas from adhering to a portion other than the first processing region PR1 of the substrate W.

The controller 90 may be configured to vary the relative speed of the turntable 21 and each placing table 22 with respect to the first nozzle 60, when the turntable 21 and each placing table 22 pass below the first nozzle 60 in the vertical direction. That is, the upper surface of the substrate W to be subjected to the substrate processing has a large surface area on the outer peripheral portion and a small surface area at the central portion. By varying the relative speed of the turntable 21 and each placing table 22 according to the surface area of the upper surface of the substrate W, a time in which the first processing regions PR1 opposes the substrate W can be made uniform in the radial direction of the substrate W.

For example, as illustrated in FIG. 8B through FIG. 8D, the substrate processing apparatus 1 sets the revolving speed of the turntable 21 to a low speed at the outer peripheral portion of the substrate W and to a high speed at the central portion of the substrate W. In other words, the controller 90 increases the speed of the turntable 21 at the position opposing the central portion of the substrate W when compared to the position opposing the outer peripheral portion of the substrate W. FIG. 8B through FIG. 8D illustrate an example in which the upper surface of the substrate W is divided into three regions, namely, a low speed region SP1, a medium speed region SP2, and a high speed region SP3, and the speed is varied based on an outer edge of the first nozzle 60 crossing a boundary of each of the regions SP1, SP2, and SP3. However, the revolving speed of the turntable 21 is not limited to being varied stepwise, and may be varied gradually (smoothly) according to the movement of the radial position on the substrate W.

Accordingly, the substrate processing apparatus 1 can cause the first processing region PR1 to uniformly oppose each rotating substrate W, by varying the revolving speed of the turntable 21. Hence, the substrate processing apparatus 1 can further promote the uniformity of the film formed on the surface of the substrate W when forming the film on the substrate W. The revolving speed of the turntable 21 is varied in the example described above, however, the substrate processing apparatus 1 is not limited such a configuration, and may be configured to vary the rotational speed of each placing table 22 while maintaining the revolving speed of the turntable 21 constant.

As illustrated in FIG. 7D, when the controller 90 rotates the turntable 21 clockwise to a range of approximately 90° from a rotation start position, the controller 90 temporarily ends the adsorption process. Thus, the controller 90 can move each substrate W (each placing table 22) to a position where the substrate W once passed the second nozzle 70 during the adsorption process.

Thereafter, the controller 90 performs an oxidation process as a film forming process (step S105 in FIG. 6). In addition, between the adsorption process and the oxidation process, an interval in which the discharging of the processing gas is stopped and the discharging of the purge gas and the suction of the gas are performed, may be set.

During the oxidation process, the controller 90 operates the gas exhauster 40 to suck the gas by each of the second nozzles 70, while operating the gas supply 30 to discharge the reaction gas and the purge gas from each of the second nozzles 70. In this state, the controller 90 stops the discharging and suction of the gas by each of the first nozzles 60. Moreover, the controller 90 rotates the turntable 21 in a second direction (for example, counterclockwise) while maintaining the rotation of each of the placing tables 22.

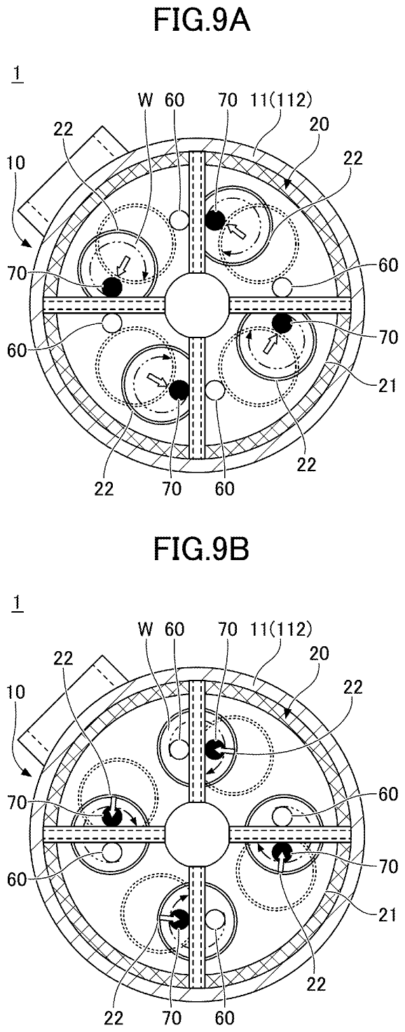

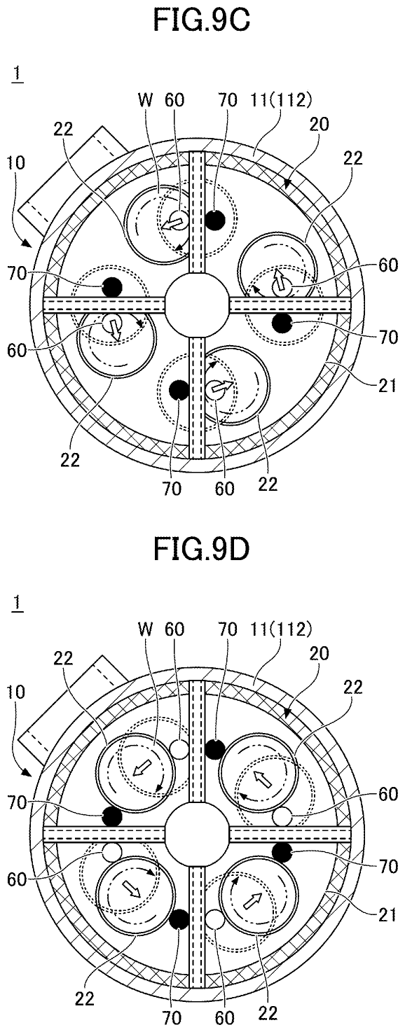

As illustrated in FIG. 9A, each substrate W placed on each placing table 22 enters below the second nozzle 70 in the vertical direction from the leading end in the counterclockwise direction, due to the counterclockwise rotation (revolution) of the turntable 21. In this state, each placing table 22 rotates at a rotational speed higher than the revolving speed of the turntable 21. The outer edge of each substrate W placed on each placing table 22 continues to rotate in the circumferential direction below the second nozzle 70 in the vertical direction, and thus, the outer edge of each substrate W opposes the second nozzle 70 for the entire circumference in the circumferential direction.

The second nozzle 70 forms the second processing region PR2 for discharging the reaction gas and the purge gas and sucking the gases, below the second nozzle 70 in the vertical direction (refer to FIG. 5A). Thus, the reaction gas is supplied to the adsorption gas on the outer edge of the substrate W passing below the second nozzle 70 in the vertical direction, and the reaction between the adsorption gas and the reaction gas can be promoted. Further, as illustrated in FIG. 9B, each substrate W passes below the partition wall member 122 and the second nozzle 70 in the vertical direction due to the counterclockwise rotation of the turntable 21, and the reaction gas can also be supplied to the central portion of the upper surface of each substrate W.

As illustrated in FIG. 9C, the trailing end in the clockwise direction of each substrate W passes below the second nozzle 70 in the vertical direction, due to the counterclockwise rotation of the turntable 21. Similar to the adsorption process, each substrate W opposes the second nozzle 70 a plurality of times as the placing table 22 rotates, while passing below the second nozzle 70 in the vertical direction. As a result, the reaction gas is supplied onto the entire surface of each substrate W.

Further, the second nozzle 70 also forms the purge gas discharge region PR22 on the outer side of the reaction gas discharge region PR21, and thus, it is possible to easily control the reaction gas discharge region PR21 by preventing the reaction gas from spreading. Further, the second nozzle 70 sucks the gas in the suction region PR23 on the outer side of the purge gas discharge region PR22, thereby reducing the reaction gas remaining near the upper surface of the substrate W, and preventing the reaction gas from being directed toward a portion other than the second processing region PR2 of the substrate W.

During the oxidation process, the controller 90 may be configured to also vary the relative speed of the turntable 21 and each placing table 22 with respect to the second nozzle 70, when the turntable 21 and each placing table 22 pass below the second nozzle 70 in the vertical direction. By varying the relative speed of the turntable 21 and each placing table 22, a time in which the second processing regions PR2 opposes the substrate W can be made uniform in the radial direction of the substrate W.

As illustrated in FIG. 9D, when the controller 90 rotates the turntable 21 counterclockwise to a range of approximately 90° from the rotation start position, the controller 90 temporarily ends the oxidation process. Thus, the controller 90 can move each substrate W (each placing table 22) to a position where the substrate W once passed the first nozzle 60 during the oxidation process.

After performing each of the adsorption process and the oxidation process once, the controller 90 determines whether or not to end the substrate processing (step S106 in FIG. 6). The film thickness may be determined by estimating the number of times the adsorption process and the oxidation process are performed, or estimating a time period for which the adsorption process and the oxidation process are performed. Alternatively, the film thickness of the substrate W may actually be measured by a film thickness measuring device (not illustrated) provided in the processing chamber 10. For example, when the thickness of the film formed on the substrate W reaches a target thickness, the controller 90 determines that the substrate processing is to be ended (YES in step S106), and the process advances to step S107. On the other hand, when the thickness of the film formed on the substrate W does not reach the target thickness, the controller 90 determines that the substrate processing is to be continued (No in step S106), and the process returns to step S104 to repeat the adsorption process and the oxidation process again.

Finally, the controller 90 performs a substrate unloading process to unload each substrate W from the processing chamber 10 (step S107 in FIG. 6). During the substrate unloading process, the controller 90 opens the gate valve 15 and unloads each processed substrate W by the transport device 2 through the side opening 112a.

As described above, the substrate processing apparatus 1 and the substrate processing method can satisfactorily supply the gas to the entire surface of the substrate W by causing revolving (reciprocating operation) of the turntable 21 and rotation of each placing table 22, so that the center of the substrate W passes the first nozzle 60 and the second nozzle 70. As a result, an in-plane uniformity of the substrate processing with respect to the substrate W can be enhanced, and further improve the quality of the substrate processing.

The substrate processing apparatus 1 and the substrate processing method according to the present disclosure are not limited to the embodiment described above, and various modifications may be made. For example, the first nozzle 60 and the second nozzle 70 may be configured to perform only the discharging of the processing gas and the suction of the gas, by omitting the purge gas dischargers 64 and 74, respectively.

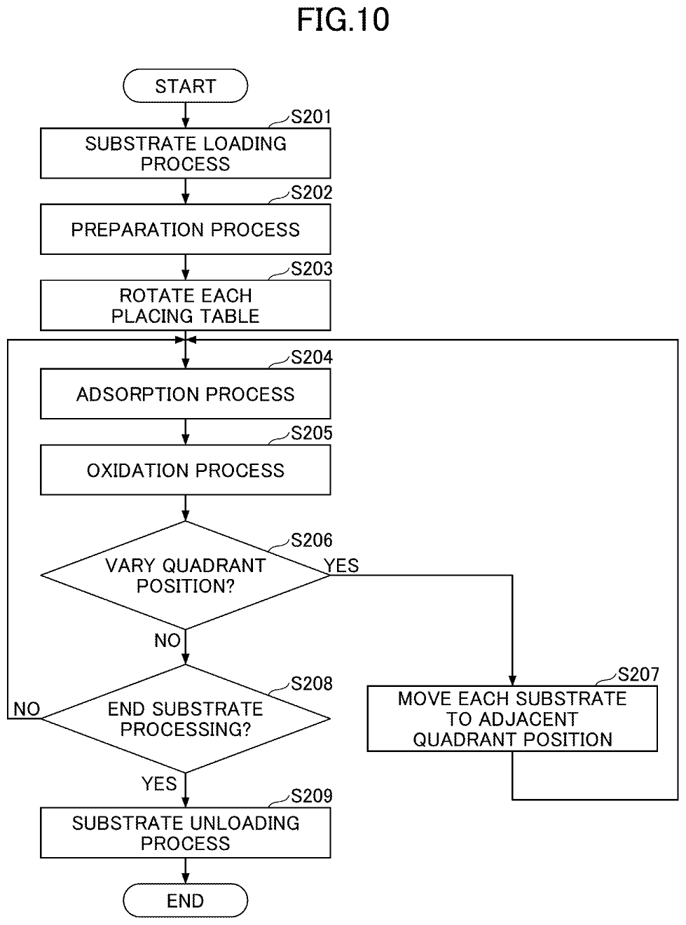

In addition, as illustrated in FIG. 10, for example, in the substrate processing method according to a first modification, the position of each substrate W is shifted to a quadrant position (first through fourth quadrants Q1 through Q4) in the circumferential direction. In this case, the substrate processing method can cause each of the plurality of substrates W to oppose all of the four first nozzles 60 and the four second nozzles 70. The substrate processing method according to this first modification will be described below.

Processes of steps S201 through S209 illustrated in FIG. 10 are performed under the control of the controller 90. The processes of steps S201 through S205 illustrated in FIG. 10 are substantially the same as the processes of steps S101 through S105 of the embodiment described above and illustrated in FIG. 6, and a detailed description thereof will be omitted. In a process of step S206, the controller 90 determines whether or not to vary the first through fourth quadrants Q1 through Q4 in which the gas is discharged to each substrate W. For example, the controller 90 counts the number of times the adsorption process and the oxidation process are repeated, and determines that the quadrant position is to be varied when the number of repetitions reaches a preset value (YES in step S206). On the other hand, when the number of repetitions is less than the preset value, the controller 90 determines that the quadrant position is to be maintained (NO in step S206), and the process returns to the process of step S204.

When varying the quadrant position, the controller 90 moves each substrate W from the current quadrant position to an adjacent quadrant position by rotating the turntable 21 by 90°, for example (step S207). In this state, the discharging of the gases from the first nozzle 60 and the second nozzle 70 is stopped. For example, the substrate W in the first quadrant Q1 moves to the second quadrant Q2 according to the revolution of the turntable 21. Thus, each substrate W is disposed at a position where the substrate W can oppose the adjacent first nozzle 60 and second nozzle 70 during the next adsorption process and oxidation process. Subsequent processes of steps S208 and S209 are substantially the same as the processes of steps S106 and S107 of the above described embodiment illustrated in FIG. 6, and a detailed description thereof will be omitted.

As described above, in the substrate processing method according to the first modification, the quadrant position of each substrate W is varied when performing the adsorption process and the oxidation process a plurality of times. Thus, the substrate processing apparatus 1 and the substrate processing method can eliminate machine differences among the first nozzles 60 and machine differences among the second nozzles 70, to promote the uniformity of the substrate processing (uniformity of the film thickness or the like) among the substrates W, and further improve the accuracy of the substrate processing.

In the substrate processing apparatus 1 and the substrate processing method according to the embodiment described above, the gases are supplied and discharged by the first nozzle 60 and the second nozzle 70 by reciprocating the turntable 21. However, the substrate processing apparatus 1 and the substrate processing method may be configured to supply and discharge the gases by the first nozzle 60 and the second nozzle 70 while rotating the turntable 21 in one direction, namely, the clockwise direction or the counterclockwise direction in FIG. 1, without reciprocating the turntable 21. That is, during the adsorption process of the embodiment, the substrate W is moved clockwise to be disposed at the adjacent quadrant position, and during the oxidation process thereafter, the substrate W is returned to the original quadrant position by moving the substrate W counterclockwise. However, even in a case where the substrate W is moved clockwise during the oxidation process, the processing can still be performed by the second nozzle 70.

Accordingly, the substrate processing apparatus 1 can obtain effects that are the same as the effects described above, by switching a timing of the discharge and suction of the gas by the first nozzle 60 and a timing of the discharge and suction of the gas by the second nozzle 70, while rotating the turntable 21 in one direction. In this state, the substrate processing apparatus 1 may perform an intermittent rotation in which the turntable 21 is stopped every time the quadrant position is switched, or perform a continuous rotation in which the turntable 21 is continuously rotated regardless of the switching of the quadrant position. Alternatively, the substrate processing apparatus 1 may repeat the rotation of the turntable 21 in one direction a plurality of times to perform the processing by the first nozzle 60 and the second nozzle 70, and thereafter repeat the rotation of the turntable 21 in an opposite direction a plurality of times to perform the processing by the first nozzle 60 and the second nozzle 70.

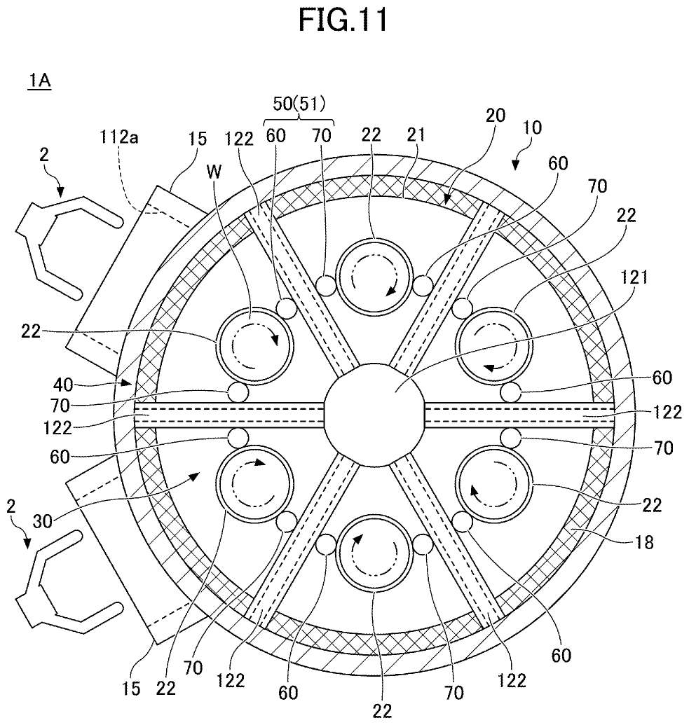

A substrate processing apparatus 1A according to a second modification illustrated in FIG. 11 differs from the substrate processing apparatus 1 according to the embodiment described above in that six substrates W are accommodated inside the processing chamber 10 and subjected to the substrate processing. In this case, the substrate processing apparatus 1A may include six partition wall members 122, six first nozzles 60, and six second nozzles 70 corresponding to the number of six placing tables 22, respectively. In short, the number of substrates W to be processed inside the processing chamber 10 is not particularly limited, and an appropriate number of first nozzles 60 and second nozzles 70 may be provided according to the number of substrates W to be processed.

In the substrate processing apparatuses 1 and 1A, the nozzle structure 50 does not require the first nozzle 60 and the second nozzle 70 with respect to one substrate W to be processed, and the nozzle structure 50 may instead include a single nozzle 51 which can switch the processing gas (the adsorption gas or the reaction gas) to be discharged. Alternatively, the substrate processing apparatus 1 may be configured to perform various processes (for example, the adsorption process, the oxidation process, and an etching process) by providing three or more nozzles in the nozzle structure 50 with respect to one substrate W.

The technical concepts and effects of the present disclosure described above in the embodiment and modifications will be described below.

The substrate processing apparatuses 1 and 1A according to a first aspect of the present disclosure includes a processing chamber 10; a turntable 21 rotatably provided inside the processing chamber 10; a plurality of placing tables 22 rotatable with respect to the turntable 21 and placed with a plurality of substrates W, respectively, at positions separated from a rotation center of the turntable 21; and a plurality of nozzles 51 disposed at positions passing centers of the plurality of placing tables 22 as the turntable 21 rotates, wherein the plurality of nozzles 51 include a processing gas discharger 63 or 73 configured to discharge a processing gas with respect to the plurality of substrates W on the plurality of placing tables 22 that move with the rotation of the turntable 21, in a radial range shorter than a radius of the plurality of substrates W; and a gas suction section 65 or 75 configured to suck the gas at an outer side of the processing gas discharger 63 or 73.

According to the configuration described above, the substrate processing apparatuses 1 and 1A can supply the processing gas to the entire opposing surface of each substrate W rotated by the turntable 21 and each placing table 22, by the plurality of nozzles 51. Hence, the substrate processing apparatuses 1 and 1A can accurately perform the substrate processing on each substrate W. Further, the substrate processing apparatuses 1 and 1A can simultaneously process a plurality of substrates W accommodated inside the processing chamber 10, and thus greatly improve productivity.

In addition, the plurality of nozzles 51 include a first nozzle 60 that discharges an adsorption gas to be adsorbed to the substrate W as the processing gas from the processing gas discharger 63, and a second nozzle 70 that discharges a reaction gas that reacts with the adsorption gas adsorbed onto the substrate W from the processing gas discharger 73. Thus, the substrate processing apparatuses 1 and 1A can use the nozzles 51 depending on the type of gas, and stably perform the substrate processing on each substrate W.

Further, a period in which the first nozzle 60 discharges the adsorption gas and the period in which the second nozzle 70 discharges the reaction gas are mutually different. Thus, the substrate processing apparatus 1 can perform the process of discharging the adsorption gas and the process of discharging the reaction gas at different timings, and easily separate the gases during the substrate processing.

Moreover, the processing chamber 10 includes a plurality of first nozzles 60 at equal intervals along the circumferential direction, and a plurality of second nozzles 70 at equal intervals along the circumferential direction. For this reason, the substrate processing apparatus 1 can uniformly perform the substrate processing on the substrates W.

The processing chamber 10 includes a partition wall member 122 which extends from the center of the processing chamber 10 toward a sidewall 112 of the processing chamber 10 and fixes the first nozzle 60 and the second nozzle 70. Thus, the substrate processing apparatus 1 can firmly support the first nozzle 60 and the second nozzle 70 inside the processing chamber 10.

The first nozzle 60 is fixed to a side surface of the partition wall member 122 in a first rotation direction of the turntable 21, and the second nozzle 70 is fixed to a side surface of the partition wall member 122 in the second rotation direction opposite to the first rotation direction of the turntable 21. Thus, the substrate processing apparatus 1 can partition the region of the first nozzle 60 and the region of the second nozzle 70 by the partition wall member 122 interposed therebetween, and reduce the mixing of the adsorption gas and the reaction gas.

The plurality of nozzles 51 include purge gas dischargers 64 and 74 for discharging a purge gas, disposed between the processing gas dischargers 63 and 73 and the gas suction sections 65 and 75, respectively. Thus, the substrate processing apparatus 1 can suitably control the processing gas discharge method by the purge gas.

In addition, at least one of the plurality of nozzles 51 includes an antenna 78 for generating plasma inside the processing gas dischargers 63 and 73. Thus, the substrate processing apparatus 1 can supply the plasmatized processing gas with respect to the substrate W.

The substrate processing apparatus 1 may include a gas supply 30 configured to supply the processing gas to the nozzle 51; a gas exhauster 40 configured to suck the gas from the nozzle 51; and a controller 90 configured to control rotation of the gas supply 30, the gas exhauster 40, the turntable 21, and the plurality of placing tables 22, wherein the controller 90 rotates the plurality of placing tables 22, and rotates the turntable 21 in a state where the supply of the processing gas by the gas supply and the suction of the gas by the gas exhauster 40 are performed. Thus, the substrate processing apparatus 1 can blow the processing gas to a narrow range of the substrate W moved by the turntable 21 and suck the gas. Further, the substrate processing can be performed on the entire surface of the substrate W rotated by the placing table 22.

Moreover, the controller 90 reciprocates the turntable 21 relative to the plurality of nozzles 51. Thus, the substrate processing apparatus 1 can perform the substrate processing with each nozzle 51 and each placing table 22 stably opposing each other.

The controller 90 increases the speed of the turntable 21 at the position opposing the center of the substrate W compared to the speed at the position opposing the outer edge of the substrate W. Thus, the substrate processing apparatus 1 can further enhance the in-plane uniformity of the substrate processing with respect to the substrate W.

According to a second aspect of the present disclosure, a substrate processing method is for a substrate processing apparatus 1 which includes a processing chamber 10; a turntable 21 rotatably provided inside the processing chamber 10; a plurality of placing tables 22 rotatable with respect to the turntable 21 and placed with a plurality of substrates W, respectively, at positions separated from a rotation center of the turntable 21; and a plurality of nozzles 51 disposed at positions passing centers of the plurality of placing tables 22 as the turntable 21 rotates. The substrate processing method includes discharging the processing gas in a radial range shorter than a radius of the plurality of substrates W placed on the plurality of placing tables 22 by a processing gas discharger 63 or 73 of the plurality of nozzles 51, and sucking the gas at an outer side of the processing gas discharger 63 or 73 by a gas suction section 65 or 75 of the plurality of nozzles 51; and rotating the plurality of placing tables 22 relative to the turntable 21, and moving the plurality of placing tables 22 by the rotation of the turntable 21 so as to oppose the plurality of nozzles 51. In this case, the substrate processing method can promote uniformity of the substrate processing and improve the productivity.

According to one aspect of the present disclosure, it is possible to promote uniformity of the substrate processing and to improve the productivity.

While certain embodiments of the substrate processing apparatuses 1 and 1A and the substrate processing method have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a processing chamber;
a turntable rotatably provided inside the processing chamber;
a plurality of placing tables rotatable with respect to the turntable and placed with a plurality of substrates, respectively, at positions separated from a rotation center of the turntable; and
a plurality of nozzles disposed at positions passing centers of the plurality of placing tables as the turntable rotates, wherein
the plurality of nozzles include:
a processing gas discharger configured to discharge a processing gas with respect to the plurality of substrates on the plurality of placing tables that move with the rotation of the turntable, in a radial range shorter than a radius of the plurality of substrates; and
a gas suction section configured to suck a gas at an outer side of the processing gas discharger.

2. The substrate processing apparatus as claimed in claim 1, wherein the plurality of nozzles include:
a first nozzle configured to discharge an adsorption gas to be adsorbed to the plurality of substrates as the processing gas from the processing gas discharger; and
a second nozzle configured to discharge a reaction gas reacting with the adsorption gas adsorbed onto the plurality of substrates from the processing gas discharger.

3. The substrate processing apparatus as claimed in claim 2, wherein a period in which the first nozzle discharges the adsorption gas and a period in which the second nozzle discharges the reaction gas are mutually different.

4. The substrate processing apparatus as claimed in claim 2, wherein the processing chamber includes a plurality of first nozzles arranged at equal intervals along a circumferential direction, and a plurality of second nozzles arranged at equal intervals along the circumferential direction.

5. The substrate processing apparatus as claimed in claim 4, wherein the processing chamber includes a partition wall member extending from a center of the processing chamber toward a sidewall of the processing chamber and fixing the first nozzle and the second nozzle.

6. The substrate processing apparatus as claimed in claim 5, wherein:
the first nozzle is fixed to a side surface of the partition wall member in a first rotation direction of the turntable, and
the second nozzle is fixed to a side surface of the partition wall member in a second rotation direction opposite to the first rotation direction of the turntable.

7. The substrate processing apparatus as claimed in claim 1, wherein the plurality of nozzles include a purge gas discharger configured to discharge a purge gas between the processing gas discharger and the gas suction section.

8. The substrate processing apparatus as claimed in claim 1, wherein at least one nozzle among the plurality of nozzles includes an antenna configured to generate plasma inside the processing gas discharger.

9. The substrate processing apparatus as claimed in claim 1, further comprising:
a gas supply configured to supply the processing gas to the plurality of nozzles;
a gas exhauster configured to suck the gas from the plurality of nozzles; and
a controller configured to control rotation of the gas supply, the gas exhauster, the turntable, and the plurality of placing tables,
wherein the controller rotates the plurality of placing tables, and rotates the turntable in a state where the supply of the processing gas by the gas supply and the suction of the gas by the gas exhauster are performed.

10. The substrate processing apparatus as claimed in claim 9, wherein the controller controls the turntable to reciprocate relative to the plurality of nozzles.

11. The substrate processing apparatus as claimed in claim 9, wherein the controller increases a speed of the turntable at a position opposing a center of the substrate more than at a position opposing an outer edge of the substrate.

12. A substrate processing method for a substrate processing apparatus comprising:
a processing chamber;
a turntable rotatably provided inside the processing chamber;
a plurality of placing tables rotatable with respect to the turntable and placed with a plurality of substrates, respectively, at positions separated from a rotation center of the turntable; and
a plurality of nozzles disposed at positions passing centers of the plurality of placing tables as the turntable rotates,
the substrate processing method comprising:
discharging the processing gas in a radial range shorter than a radius of the plurality of substrates placed on the plurality of placing tables by a processing gas discharger of the plurality of nozzles, and sucking a gas at an outer side of the processing gas discharger by a gas suction section of the plurality of nozzles; and
rotating the plurality of placing tables relative to the turntable, and moving the plurality of placing tables by the rotation of the turntable so as to oppose the plurality of nozzles.
